(19) United States
(12) Patent Application Publication
(10) Pub. No.: US 2026/0060102 A1
(43) Pub. Date: Feb. 26, 2026

(54) SEMICONDUCTOR PACKAGE STRUCTURE AND MANUFACTURING METHODS THEREOF

(71) Applicant: Samsung Electronics Co., Ltd., Suwon-si (KR)

(72) Inventor: Peng ZHANG, Suzhou (CN)

(73) Assignee: Samsung Electronics Co., Ltd., Suwon-si (KR)

(21) Appl. No.: 18/885,927

(22) Filed: Sep. 16, 2024

(30) Foreign Application Priority Data
Aug. 21, 2024 (CN) 202411148891.5

(51) Int. Cl. H01L 23/538; H01L 23/00; H01L 23/31; H01L 23/367; H01L 23/498; H01L 25/00; H01L 25/065

(52) U.S. Cl. CPC H01L 23/5385; H01L 23/3107; H01L 24/48; H01L 25/0657; H01L 25/50; H01L 23/367; H01L 23/49816; H01L 2224/48227; H01L 2225/06562

(57) ABSTRACT

The semiconductor package structure may include a support substrate, a chip stack body on a central region of the support substrate and including a plurality of chips; a first interface on a first edge region of the support substrate and a first redistribution layer on the first interface; a second interface on a second edge region and a second redistribution layer on the second interface; a bonding wire electrically connecting the plurality of chips to the first redistribution layer and the second redistribution layer, respectively; a dummy chip on the chip stack body; and an encapsulation layer, packaging the chip stack body, the dummy chip, the first interface, the second interface and the bonding wire, wherein an upper surface of the dummy chip is coplanar with an upper surface of the encapsulation layer, and external connection terminals on the first redistribution layer and the second redistribution layer.

### CROSS-REFERENCE TO RELATED APPLICATION

This application claims benefit of priority to Chinese Patent Application No. 202411148891.5 filed on Aug. 21, 2024 in the Chinese Intellectual Property Office, the disclosures of which are incorporated herein by reference in their entirety.

### BACKGROUND

### 1. Field

Some example embodiments of inventive concepts relate to a semiconductor package, for example to a semiconductor package structure and manufacturing methods thereof.

### 2. Description of the Related Art

Usually, in order to realize a stack of multiple chips, wire bonding technology may be used to connect respective chips constituting the package structure with the corresponding substrate, and then package bare chips stacked on the substrate through a MOLD engineering to form the package structure.

FIG. 1 illustrates a semiconductor package structure according to the related art. Referring to FIG. 1, a semiconductor package structure 10 may include, for example, a substrate 1, a plurality of chips 2, a bonding wire 3, an encapsulation layer 4, and one or more solder balls 5. The plurality of chips 2 are stacked and fixed to an upper side of the substrate 1 in a manner such that, for example, the active surfaces face upward. The plurality of chips 2 are staggered from one another to expose one or more pads on the active surface of each chip 2. The bonding wire 3 electrically connects each of the plurality of chips 2 with one another via (for example, by) the pads and is electrically connected to the substrate 1. The solder balls 5 are disposed at a lower side of the substrate 1 to output signals from the chips 2 and/or receive signals from the outside.

The above-described semiconductor package structure has at least the following problems: first, since the package structure includes the substrate, thickness of the package is difficult to reduce; second, an interconnect density of a substrate level package structure is relatively low; and third, for an ultra-thin package structure, the use of a thin-type substrate may not only easily cause an occurrence of a reliability risk, but also increases difficulty of the packaging process.

The above information described in the Background Art is only used for enhancing the understanding for the background of present inventive concepts. Therefore, the above information may include information of the related art that does not form and that is already known to those ordinarily skilled in the art.

### SUMMARY

In order to address the above problems, example embodiments of inventive concepts include, for example, a semiconductor package structure having a high interconnect density, a small or relatively small thickness, and/or reinforcing bottom heat dissipation, and manufacturing methods thereof.

According to some example embodiments of inventive concepts, a semiconductor package structure may includes: a support substrate; a chip stack body on a central region of the support substrate and comprising a plurality of chips stacked on the support substrate; a first interface on a first edge region of the support substrate, and a first redistribution layer on an upper surface of the first interface; a second interface on a second edge region of the support substrate, the second region opposite to the first edge region, and a second redistribution layer on an upper surface of the second interface; a bonding wire, electrically connecting the plurality of chips to the first redistribution layer and to the second redistribution layer, respectively; a dummy chip on the chip stack body; and an encapsulation layer on the support substrate and at least partially encapsulating the chip stack body, the dummy chip, the first interface, the second interface, and the bonding wire, wherein n upper surface of the dummy chip is coplanar with an upper surface of the encapsulation layer, and external connection terminals are at least partially exposed by the encapsulation layer, the external connection being on the first redistribution layer and the second redistribution layer, respectively.

According to some example embodiments of inventive concepts, a method of manufacturing a semiconductor package structure may include: disposing a first interface and a second interface in a first edge region of the support substrate and a second edge region opposite to the first edge region, respectively, wherein a first redistribution layer is formed on an upper surface of the first interface, and a second redistribution layer is formed on an upper surface of the second interface; stacking a plurality of chips on a central region of the support substrate; electrically connecting the plurality of chips to the first redistribution layer and the second redistribution layer, respectively, using a bonding wire; disposing a dummy chip on a chip stack body, the stack body including the plurality of chips; and encapsulating the plurality of chips, the dummy chip, the first interface, the second interface and the bonding wire on the support substrate using an encapsulation layer, wherein an upper surface of the disposed dummy chip is coplanar with an upper surface of the encapsulation layer, and the encapsulation layer at least partially exposes external connection terminals, the external connection terminals disposed on the first redistribution layer and on the second redistribution layer, respectively.

### BRIEF DESCRIPTION OF THE DRAWINGS

The above and other features and advantages of the present disclosure will become explicit from the following detailed description for example embodiments of the present disclosure, taken in conjunction with drawings. In the drawings, the same drawing marks will always indicate same components.

FIG. 1 illustrates a semiconductor package structure according to the related art.

FIG. 2 illustrates a semiconductor package structure according to some example embodiments of inventive concepts.

FIG. 3 illustrates a process flowchart of a manufacturing method of the semiconductor package structure according to some example embodiments of inventive concepts.

FIGS. 4, 5 and 6 illustrate respective steps of a manufacturing method of the semiconductor package structure according to some example embodiments of inventive concepts.

### DETAILED DESCRIPTION

Hereinafter, various example embodiments of inventive concepts will be fully described by referring to drawings of some example embodiments illustrated therein. However, the present inventive concepts may be implemented in many different forms, and should not be interpreted to be limited to the example embodiments elaborated hereto. On the contrary, the description will be thorough and complete by providing these example embodiments, and the example embodiments will convey the scope of the present disclosure to those ordinarily skilled in the art. In the drawings, to aid in clarity, sizes of, for example, a layer and/or an area may be exaggerated.

For easy description, spatially relative terms (such as “below”, “beneath”, “under”, “above”, “on”, etc.) are used herein to describe a relationship between one element and the other elements as illustrated in the drawings. It should be understood that, the spatially relative terms also intend to include different orientations of a device in a usage or an operation, other than the orientations as described in the drawings. For example, if the device in the drawings is flipped, the element described to be “beneath” or “below” the other element shall be modified as “above” the other element. Therefore, the term “below” may include the “upper” and “lower” orientations. The device can be directed toward another orientation (rotated by 90 degree or located in another orientation), and the spatially relative terms used herein should be interpreted accordingly.

FIG. 2 illustrates a semiconductor package structure according to some example embodiments of inventive concepts. Referring to FIG. 2, the semiconductor package structure 100 may include: a support substrate 110; a chip stack body STK on a central region CR of the support substrate 110 and including a plurality of chips 120 stacked on the support substrate 110; a first interface 130, disposed on a first edge region ER1 of the support substrate 110, and a first redistribution layer 131 formed on an upper surface 130U of the first interface 130; a second interface 140, disposed on a second edge region ER2 of the support substrate, the second region 110 ER2 being opposite to the first edge region ER1, and a second redistribution layer 141 formed on an upper surface 140U of the second interface 140; a bonding wire 150 electrically connecting the plurality of chips 120 to the first redistribution layer 131 and to the second redistribution layer 141, respectively; a dummy chip 160 on the chip stack body STK; and an encapsulation layer 170, the encapsulation layer 150 packaging (for example, mounting, and/or encapsulating or at least partially encapsulating) the chip stack body STK, the dummy chip 160, the first interface 130, the second interface 140, and the bonding wire 150 on the support substrate 110, wherein an upper surface 160U of the dummy chip 160 may be coplanar or substantially coplanar with an upper surface 170U of the encapsulation layer 170, and the encapsulation layer 170 may expose or at least partially expose external connection terminals 180, the external connection terminals 180 disposed on the first redistribution layer 131 and on the second redistribution layer 141.

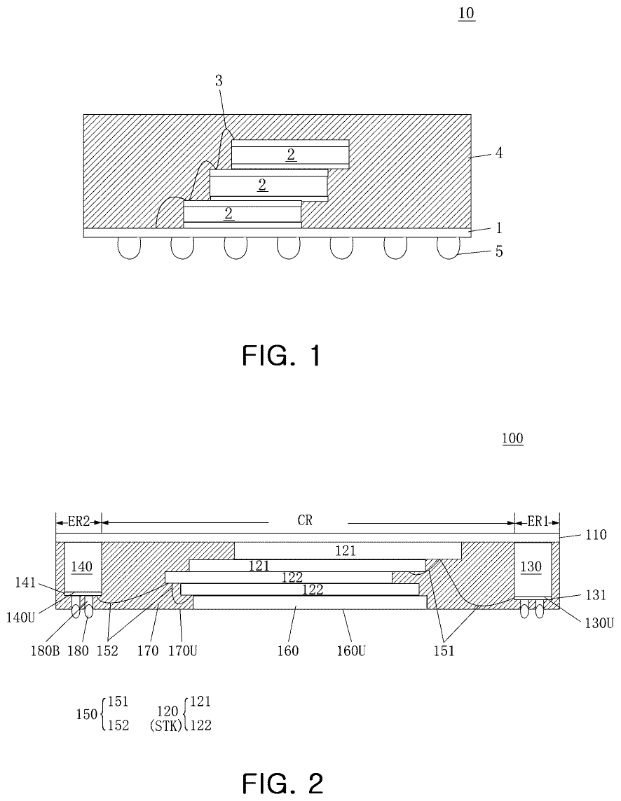

The semiconductor package structure according to some example embodiments of inventive concepts may electrically connect the bonding wire to, for example, an interconnect structure, including, for example, the first redistribution layer 131 and/or second redistribution layer 141, the redistribution layer(s) 131 and/or 142 respectively formed on the upper surface(s) of the first interface 130 and/the second interface 140 by (respectively) disposing the said interface(s) on the first edge region ER1 and/or the second edge region ER2, of the support substrate. Compared to the semiconductor package structure according to the related art as illustrated in FIG. 1, the thickness of the substrate may be canceled or reduced, the density of the interconnect structure may be increased, so as to reduce the total thickness of the semiconductor package structure while improving the integration of the semiconductor package structure.

In some example embodiments, the support substrate 110 may be formed of or include, for example, a resin film, such as, for example, an EMC film, but example embodiments are not limited thereto. The support substrate 110 may be formed as or include, for example, a flexible substrate and/or a rigid substrate. The support substrate 110 may include a central region CR and edge regions ER. The edge regions ER may be at both sides of the central region CR. The edge regions ER may include a first edge region ER1 at a first side of the support substrate 110 and a second edge region ER2 at a second side of the support substrate 110, the first side opposite to the second side. Circuit elements may or may not be not formed in and/or on the first edge region ER1 and the second edge region ER2.

In some example embodiments, each of the plurality of chips 120 included in the chip stack body STK may include an active surface and a passive surface. A circuit pattern, a wiring, a pad and/or an input/output terminal may be formed on the active surface of each chip 120. The passive surface may be backed against (for example, be opposite to) the active surface. In some example embodiments, the active surface of each chip 120 may face the dummy chip 160, and the passive surface of each chip 120 may face the support substrate 110.

In some example embodiments, the plurality of chips 120 may include a plurality of first chips 121 on the support substrate 110 and a plurality of second chips 122 between (for example, vertically between) the plurality of first chips 121 and the dummy chip 160. Each of the plurality of first chips 121 may be positioned, for example shifted or offset from one another, along a first horizontal direction (e.g., +X direction), as to expose or at least partially expose a first pad PD1 (not shown) on a respective active surface thereof. Each of the plurality of second chips 122 may be, for example, shifted or offset from one another along a second horizontal direction (e.g., −X direction) opposite to the first horizontal direction +X, as to expose a second pad PD2 on a respective active surface thereof.

In some example embodiments, the bonding wire 150 may include a first bonding wire 151 and a second bonding wire 152. The first bonding wire 151 may electrically connect the first pad PD1 to the first redistribution layer 131. The second bonding wire 152 may electrically connect the second pad PD2 to the second redistribution layer 141. For example, since a shifting or offset direction of each of the plurality of first chips 121 is different from a shifting or offset direction of each of the plurality of second chips 122, a wider space may be formed (for example, defined or at least partially defined) between the chip stack body STK and the first interface 130 to accommodate or allow for a wire loop of the, for example, a relatively long, first bonding wire 151, and a closer interval may be formed between the chip stack body STK and the second interface 140 to shorten a length of (for example to accommodate or allow for a shorter length of) the first bonding wire 151, such that not only a density of the first bonding wire 151 may be improved to increase integration, but also a resistance of the second bonding wire 152 may be reduced to accelerate signal transmission speed.

In some example embodiments, at least one of an upper surface 130U of the first interface 130 and an upper surface 140U of the second interface 140 may be lower than an upper surface 160U of the dummy chip 160. For example, the upper surface 130U of the first interface 130 and the upper surface 140U of the second interface 140 may each be coplanar with the active surface of an uppermost chip of the plurality of chips 120, but example embodiments are not limited thereto. Accordingly, an uppermost chip of the plurality of chips 120 (e.g., the second chip 122) of the chip stack body STK may have abundant wire bonding space, such that the second bonding wire 152 may be relatively short and densely disposed between the second pad PD2 and the second redistribution layer 141, to increase integration.

In some example embodiments, a plurality of bumps 180B may be disposed on the first redistribution layer 131 and/or the second redistribution layer 141. The encapsulation layer 170 may surround (for example, cover or at least partially cover) side surfaces of the plurality of bumps 180B, and the external connection terminals 180 may be respectively disposed on the plurality of bumps 180B. Bumps of the plurality of bumps 180B may also be understood as being included in the first redistribution 131 and/or in the second redistribution layer 141.

In some example embodiments, any or each of the plurality of bumps 180B may have, for example, a pillar shape and may, include, for example, one or more metal material, such as, for example, at least one of copper, silver, gold and tin, but example embodiments are not limited thereto. Although FIG. 2 illustrates that the first redistribution layer 131 and the second redistribution layer 141 include the same number of bumps, inventive concepts are not limited hereto, and the first redistribution layer 131 and the second redistribution layer 141 may include different numbers of bumps, respectively.

In some example embodiments, the dummy chip 160 may not have an electrical function and may be configured to control a thickness of the encapsulation layer 170 by measurement of a height of the dummy chip. For example, when a molding process is performed, the support substrate 110 on which elements, other than the encapsulation layer 170, are formed as illustrated in FIG. 2 may be placed into the package mold. Then, a height of the upper surface 160U of the dummy chip 160 is measured, and an injection amount of the encapsulant is determined according to the measured result, such that the encapsulation layer 170 formed by a suitable amount of encapsulant to have a suitable thickness, as to expose the external connection terminals 180 (for example, such that that one or more of external connections 180 are unencapsulated by, at least partially unencapsulated by, exposed from, or at least partially exposed from the encapsulation layer 170).

In some example embodiments, the dummy chip 160 may be configured as, for example to function as a heat sink for the plurality of chips 120 to allow for quick dissipation of heat generated during operation. Since there is no or limited need or desire to additionally dispose a heat sink, the semiconductor package structure 100 may have a smaller thickness and a faster operating speed than the conventional art.

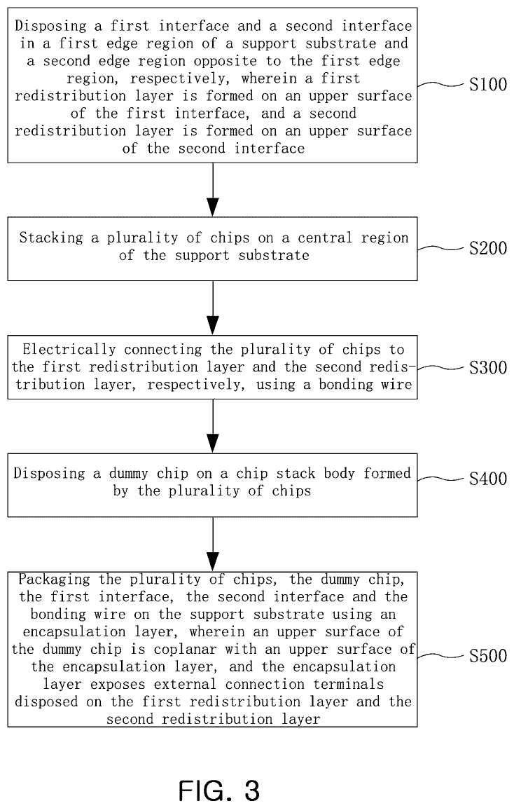

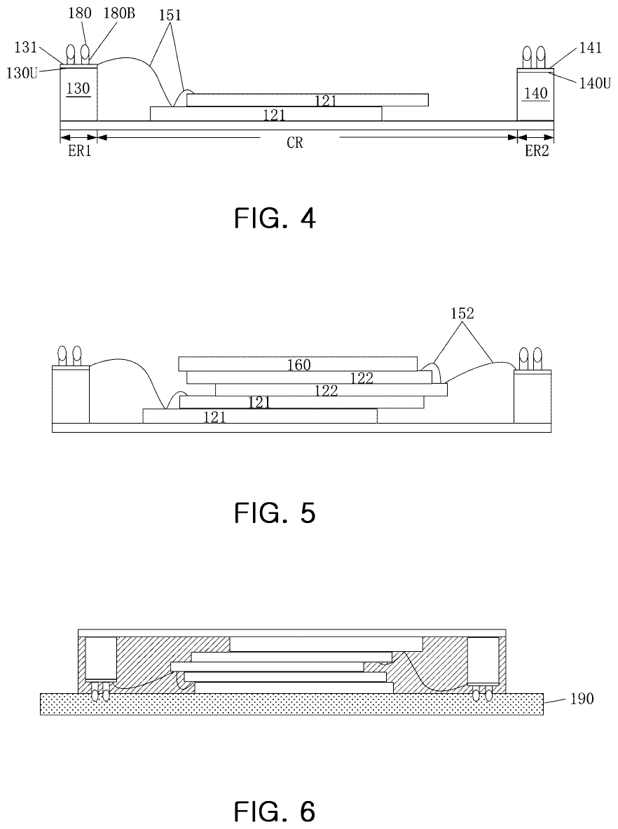

FIG. 3 illustrates a process flowchart of a manufacturing method of the semiconductor package structure according to some example embodiments of inventive concepts. FIGS. 4, 5 and 6 illustrate respective operations of a manufacturing method of the semiconductor package structure according to some example embodiments inventive concepts. Below, the manufacturing method of a semiconductor package the same as, substantially the same as, or similar to, the semiconductor package structure 100 illustrated in FIG. 2 will be described by referring to FIGS. 3-6.

Referring to FIGS. 3-5, the method of manufacturing the semiconductor package structure may include: firstly, step S100 is performed, in which the first interface 130 and the second interface 140 are disposed in the first edge region ER1 of the support substrate 110 and the second edge region ER2, respectively, the second edge ER2 being opposite to the first edge region ER1, wherein the first redistribution layer 131 is formed on the upper surface 130U of the first interface 130. and the second redistribution layer 141 is formed on the upper surface 140U of the second interface 140.

Next, step S200 is performed, in which the plurality of chips 120 are stacked on the central region CR of the support substrate 110. In some example embodiments, when the step S200 is performed, the active surface of any or each of the plurality of chips 120 may be stacked upward (for example, the plurality of chips 120 may be stacked such that the active surface of any or each of faces upwards). The plurality of chips 120 may include the plurality of first chips 121 and the plurality of second chips 122 sequentially stacked on the support substrate 110. When the step S200 is performed, any or each of the plurality of first chips 121 may be shifted (for example offset from each other) along the first horizontal direction (e.g., +X direction), to expose or at least partially expose the first pad(s) PD1 (not shown) on the respective active surface(s). Additionally, or alternatively, any or each of the plurality of second chips 122 may be shifted (for example, offset) from one another along the second horizontal direction (e.g., −X direction) opposite to the first horizontal direction +X, to expose or at least partially expose the second pad(s) PD2 on the respective active surface(s). After the step S200 has been performed (for example, as a result of step S200 being performed), the first pad(s) PD1 may be between the chip stack body STK and the first interface 130, and the second pad(s) PD2 may be between the chip stack body STK and the second interface 140.

Next, step S300 is performed, in which the bonding wire 150 is used to electrically connect the plurality of chips 120 to the first redistribution layer 131 and the second redistribution layer 141, respectively. In some example embodiments, an end of the first bonding wire 151 may be connected to a first pad PD1, and another end may be electrically connected to the first redistribution layer 131. One end of the second bonding wire 152 may be connected to the second pad PD2, and another end may be electrically connected to the second redistribution layer 141.

Next, step S400 is performed, in which the dummy chip 160 is disposed on the chip stack body STK formed by (for example, including or at least partially formed by) the plurality of chips 120, to, for example, form a structure. In some example embodiments, at least one of the upper surface 130U of the first interface 130 and the upper surface 140U of the second interface 140 may be lower than the upper surface 160U of the dummy chip 160. For example, an upper surface of the first redistribution layer 131 and an upper surface of the second redistribution layer 141 may be lower than the upper surface 160U of the dummy chip 160, but example embodiments are not limited thereto. For example, the upper surface 130U of the first interface 130 and/or the upper surface 140U of the second interface 140 may be coplanar or substantially coplanar with the active surface of the uppermost chip of the plurality of chips 120, but example embodiments are not limited thereto.

In some example embodiments, after the step S400 has been performed, the active surface of each of the plurality of chips 120 may face the dummy chip 160, and the passive surface of each of the plurality may face the support substrate 110, but example embodiments are not limited thereto.

Next, step S500 is performed, in which the encapsulation layer 170 is used to form a package, for example to package (for example, mount, encapsulate, or at least partially encapsulate) the plurality of chips 120, the dummy chip 160, the first interface 130, the second interface 140 and/or the bonding wire 150, on the support substrate 110.

After the step S500 has been performed, the upper surface of the dummy chip 160 may be, for example, coplanar or substantially coplanar with the upper surface of the encapsulation layer 170, and the encapsulation layer 170 may, for example, expose (for example, at least partially expose) any or each of external connection terminals 180 disposed on the first redistribution layer 131 and/or on the second redistribution layer 141, but example embodiments are not limited thereto.

In some example embodiments, as illustrated in FIG. 6, the step S500 of packaging using the encapsulation layer 170 may further include: inverting the obtained structure by the preceding step S400 and placing it into a package mold, the package mold including an upper cavity and a lower cavity; closing the upper cavity and the lower cavity and injecting an encapsulant; curing the encapsulant to form the encapsulation layer 170 and a package; and taking out the obtained structure (for example, removing the package) from the package mold. Although not illustrated, the package mold may be, for example, an apparatus for performing the packaging process such as a molding die, which is common in the art, but example embodiments are not limited thereto.

In some example embodiments, as illustrated in FIG. 6, the auxiliary material layer 190 may be, for example, disposed in the lower cavity of the package mold. When the upper cavity and the lower cavity are closed, the external connection terminals 180 may be pressed into the auxiliary material layer 190. Then, the encapsulant may be injected in the package mold to form the encapsulation layer 170.

In some example embodiments, as illustrated in FIG. 6, when the obtained structure at the step S500 is taken out from the package mold, the external connection terminals 180 may be demolded from the auxiliary material layer 190. Thus, the auxiliary material layer 190 may protect the external connection terminals 180 in the packaging process, to avoid it being damaged.

In some example embodiments, as illustrated in FIG. 6, the thickness of the encapsulation layer 170 to be formed may be controlled by measuring the height of the dummy chip 160 when injecting the encapsulant.

As a summary and review, firstly, the semiconductor package structure according to some example embodiments of inventive concepts cancels or reduces the thickness of the substrate of a conventional package, and reduces the thickness of the package on the whole. Secondly, the canceling or reducing of the substrate of the traditional package may also address any reliability problem(s) caused by, for example, multiple interfaces (e.g., EMC-PCB interfaces). Thirdly, the semiconductor package structure according to some example embodiments of inventive concepts uses the first interface and the second interface to realize the electrical interconnection of the plurality of chips with the redistribution layers via wire bonding, which increases interconnect density and improves electrical characteristics of the package. Fourthly, the dummy chip of the semiconductor package structure according to some example embodiments of the inventive concepts may be used as configured to be used as a heat sink, which may reinforces the bottom heat dissipation of the package, and there is lessened or no need or desire to dispose an additional heat sink, thereby not only allowing for reduction of the overall thickness of the package, but also improvement of the performance and operating speed of the package. Although example embodiments of inventive concepts have been illustrated and described, it will be understood by those ordinarily skilled in the art that various modifications and changes may be made therein without departing from the spirit and scope of inventive concepts as defined by the claims.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

What is claimed is:

1. A semiconductor package structure, comprising:
a support substrate;
a chip stack body on a central region of the support substrate and comprising a plurality of chips stacked on the support substrate;
a first interface on a first edge region of the support substrate, and a first redistribution layer on an upper surface of the first interface;
a second interface on a second edge region of the support substrate, the second edge region opposite to the first edge region, and a second redistribution layer on an upper surface of the second interface;
a bonding wire electrically connecting the plurality of chips to the first redistribution layer and to the second redistribution layer, respectively;
a dummy chip on the chip stack body; and
an encapsulation layer on the support substrate, the encapsulation layer at least partially encapsulating
the chip stack body,
the dummy chip,
the first interface,
the second interface, and
the bonding wire,
wherein an upper surface of the dummy chip is coplanar with an upper surface of the encapsulation layer, and
external connection terminals are at least partially exposed by the encapsulation layer, the external connection terminals being on the first redistribution layer and on the second redistribution layer, respectively.

2. The semiconductor package structure of claim 1, wherein each of the plurality of chips comprises an active surface and a passive surface, the active surface faces the dummy chip, and the passive surface faces the support substrate.

3. The semiconductor package structure of claim 2, wherein the plurality of chips comprises a plurality of first chips and a plurality of second chips, the plurality of second chips being between the plurality of first chips and the dummy chip,
each of the plurality of first chips is respectively offset in a first horizontal direction with respect to any of the plurality of first chips that are vertically thereabove such that a first pad is exposed on the active surface of each of the plurality of first chips, and
each of the plurality of second chips is respectively offset in a second horizontal direction with respect to any of the plurality of second chips that are vertically thereabove such that a second pad is exposed on the active surface of each of the plurality of second chips, the second horizontal direction being opposite the first horizontal direction.

4. The semiconductor package structure of claim 3, wherein the bonding wire comprises a first bonding wire and a second bonding wire,
the first bonding wire electrically connects the first pad of at least one of the plurality of first chips to the first redistribution layer, and
the second bonding wire electrically connects the second pad of at least one of the plurality of second chips to the second redistribution layer.

5. The semiconductor package structure of claim 1, wherein the upper surface of the first interface and the upper surface the second interface are lower than the upper surface of the dummy chip.

6. The semiconductor package structure of claim 2, wherein the upper surface of the first interface and the upper surface of the second interface are coplanar with the active surface of an uppermost chip of the plurality of chips.

7. The semiconductor package structure of claim 5, wherein a plurality of bumps are on the first redistribution layer and on the second redistribution layer, the encapsulation layer at least partially covers side surfaces of the plurality of bumps, and the external connection terminals are disposed on the plurality of bumps, respectively.

8. The semiconductor package structure of claim 7, wherein at least one of the plurality of bumps has a pillar shape and comprises at least one metal material.

9. The semiconductor package structure of claim 1, wherein the dummy chip does not have an electrical function.

10. The semiconductor package structure of claim 1, wherein the dummy chip is a heat sink for the plurality of chips.

11. The semiconductor package of claim 1, wherein the support substrate includes a resin film.

12. A method of manufacturing a semiconductor package structure, comprising:
disposing a first interface and a second interface on a first edge region of a support substrate and a second edge region opposite to the first edge region, respectively, wherein a first redistribution layer is formed on an upper surface of the first interface, and a second redistribution layer is formed on an upper surface of the second interface;
stacking a plurality of chips on a central region of the support substrate;
electrically connecting the plurality of chips to the first redistribution layer and to the second redistribution layer, respectively, using a bonding wire;
disposing a dummy chip on a chip stack body to form a structure, the chip stack body including the plurality of chips; and
at least partially encapsulating the plurality of chips, the dummy chip, the first interface, the second interface, and the bonding wire using an encapsulation layer to form a package,
wherein an upper surface of the dummy chip is coplanar with an upper surface of the encapsulation layer, and
external connection terminals are at least partially exposed by the encapsulation layer, the external connection terminals respectively on the first redistribution layer and on the second redistribution layer.

13. The method of claim 12, wherein the at least partially encapsulating using the encapsulation layer further comprises:
inverting the structure and placing the structure into a package mold, the package mold comprising an upper cavity and a lower cavity;
closing the upper cavity and the lower cavity and injecting an encapsulant;
curing the encapsulant to form the encapsulation layer and the package; and
removing the package from the package mold.

14. The method of claim 13, wherein an auxiliary material layer is disposed in the lower cavity of the package mold, and the external connection terminals are pressed into the auxiliary material layer when closing the upper cavity and the lower cavity.

15. The method of claim 14, wherein the external connection terminals are demolded from the auxiliary material layer when the package is removed from the package mold.

16. The method of claim 12, wherein each of the plurality of chips comprises an active surface and a passive surface, the active surface faces the dummy chip, and the passive surface faces the support substrate.

17. The method of claim 16, wherein the plurality of chips comprises a plurality of first chips and a plurality of second chips, the plurality of second chips between the plurality of first chips and the dummy chip,
each of the plurality of first chips is respectively offset in a first horizontal direction with respect to any of the plurality of first chips that are vertically thereabove such that a first pad is exposed on the active surface of each of the plurality of first chips, and
each of the plurality of second chips is respectively offset in a second horizontal direction with respect to any of the plurality of second chips vertically thereabove such that a second pad is exposed on the active surface of each of the plurality of second chips.

18. The method of claim 17, wherein the bonding wire comprises a first bonding wire and a second bonding wire,
the first bonding wire electrically connects the first pad of at least one of the plurality of first chips to the first redistribution layer, and
the second bonding wire electrically connects the second pad of at least one of the plurality of second chips to the second redistribution layer.

19. The method of claim 13, wherein the injection of the encapsulant is controlled by measuring a height of the dummy chip to form a desired thickness of the encapsulation layer.

20. The method of claim 12, wherein the dummy chip is a heat sink for the plurality of chips.
